(19) United States
(12) Patent Application Publication
(10) Pub. No.: US 2007/0045657 A1
(43) Pub. Date: Mar. 1, 2007

(54) Semiconductor substrate, semiconductor device, manufacturing method thereof, and method for designing semiconductor substrate

(75) Inventor: Kei Kanemoto, Nagano-ken (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/492,607

(22) Filed: Jul. 24, 2006

(30) Foreign Application Priority Data
Jul. 22, 2005 (JP) 2005-212748

(51) Int. Cl. H01L 29/74

(52) U.S. Cl. 257/133

(57) ABSTRACT

A semiconductor substrate, includes: a capacitance-adjusting semiconductor layer which is disposed in a predetermined region on a semiconductor substrate material and which is sufficiently thick and has a lower impurity density than that of the semiconductor substrate material; a first insulation film disposed on the capacitance-adjusting semiconductor layer; and a body layer made of a semiconductor disposed on the first insulation film.

### BACKGROUND

1. Technical Field

The present invention relates to a semiconductor substrate, a semiconductor device, a manufacturing method thereof, and a method for designing a semiconductor substrate and particularly to a technique for forming a silicon-on-insulator (SOI) structure on a semiconductor substrate

2. Related Art

In the field of semiconductor, developments are now being made on a silicon-on-insulator (SOI) technology to reduce electric consumption of integrated circuits. Devices using the SOI substrate enable drastic reduction in parasitic capacitance of the transistors and are thus known to perform faster and consume less electricity than conventional devices.

However, because the SOI substrate is manufactured by such methods as SIMOX and bonding using special manufacturing apparatuses, the cost of the substrate is very high (normally five to ten times higher than a bulk substrate). Also, because of its special structure, the device using the SOI has some disadvantages such as that the drain breakdown voltage decreases and electrostatic breakdown level lowers. Thus, to solve these problems, methods for fabricating a partial SOI structure on the bulk substrate are proposed.

For example, one of such methods is a technique of separation by bonding silicon islands (SBSI) as disclosed in a non-patent document, Separation by Bonding Si Islands (SBSI) for LSI Applications (T, Sakai et al., Second International SiGe Technology and Device Meeting Abstract, May 2004, pp. 230-231). By the SBSI technique, the SOI device can be manufactured in a conventional semiconductor line, and the SOI structure can be made only in a desired region of the bulk substrate, and, thus, an inexpensive and high-performance SOI device can be realized.

More specifically, the manufacturing method includes first forming a SiGe layer and a Si layer on a Si substrate by epitaxial growth. Then, a hole for a support is formed in the Si layer and the SiGe layer. After forming a silicon oxide (SiO₂) film or a silicon nitride (Si₃N₄) film as the support, the support is dry-etched into a form of an element region, and the Si layer/SiGe layer is continuously dry-etched. In this state, the SiGe layer is selectively etched with nitric fluoric acid to create a cavity under the Si layer in a manner that the Si layer is hanging from the support. Thereafter, the cavity is filled with the SiO₂ by oxidation to form the SOI structure.

One of the advantages of a SOI MOSFET is to reduce junction capacitance by the presence of a buried oxide film (BOX). As shown in FIG. 11, the junction capacitance is an electric capacitance generated between a source diffusion layer or a drain diffusion layer (hereinafter referred to as a “source/drain”) and the Si substrate, and the thicker the BOX is, the smaller the value of the electric capacitance becomes. When forming a thick BOX on the Si substrate by the SBSI technique, it is necessary to form a thick SiGe layer to correspond with the thick BOX. For example, when forming the BOX having a normal thickness of 200 nm with a SOI wafer by the SBSI technique now, it is necessary to form about 100 nm of SiGe.

However, when forming the SiGe layer on the Si substrate, the SiGe layer has a critical thickness depending on the density of Ge included therein, and it is not possible to grow the SiGe layer having the Ge density required for the SBSI technique (that is, required in order to increase an etching selection ratio to the Si) into a thickness of 100 nm without defects.

The critical thickness here means a maximum film thickness with which no crystal defects occur. Because SiGe has a larger crystal lattice than Si, SiGe formed on Si is under a compressive stress in order to align its lattice with Si. When the thickness of the SiGe layer exceeds a certain thickness (that is, the crystal thickness), the stress is released by generating crystal defects.

If Si is formed on SiGe having the crystal defects, the defects spread to Si and negatively influence the properties of the MOSFET. Therefore, it is inevitable to thinly form the SiGe film (e.g., 30 nm or less), and, accordingly, the buried oxide film (hereinafter also referred to as the “insulation film”) cannot be formed thickly. For these reasons, with the conventionally known SBSI technique, the junction capacitance may not necessarily be reduced sufficiently (a problem).

### SUMMARY

An advantage of the invention is to provide a semiconductor substrate, a semiconductor device, a manufacturing method thereof, and a method for designing a semiconductor substrate, by which the junction capacitance can be reduced without thickly forming an insulation film.

According to a first aspect of the invention, a semiconductor substrate includes: a capacitance-adjusting semiconductor layer which is disposed in a predetermined region on a semiconductor substrate material and which is sufficiently thick and has a lower impurity density than that of the semiconductor substrate material; an insulation film disposed on the capacitance-adjusting semiconductor layer; and a body layer made of a semiconductor disposed on the insulation film.

In this case, the “semiconductor substrate material” is a silicon (Si) substrate of a bulk, for example, and the “predetermined region” is a region (namely, an element formation region) where elements such as a transistor are formed. Further, the “capacitance-adjusting semiconductor layer” and the “body layer” are Si layers obtained by epitaxial growth, for example.

Further, “sufficiently thick” means sufficiently thicker than the semiconductor layer for buffer which is formed on the semiconductor substrate material as a base of a sacrificial semiconductor layer. By the SBSI technique, before forming the sacrificial semiconductor layer (e.g., the SiGe layer) on the semiconductor substrate material (e.g., the Si substrate), the semiconductor layer for buffer (e.g., the Si layer) is normally formed on the semiconductor substrate material as the base of the sacrificial semiconductor layer. The thickness of this semiconductor layer for buffer is between ten or more nanometers (nm) to several ten nanometers (nm). The capacitance-adjusting semiconductor layer of some aspects of the invention is sufficiently thicker than this semiconductor layer for buffer, and the thickness of the capacitance-adjusting semiconductor layer is 100 nm or more, for example.

With the semiconductor substrate of the first aspect of the invention, a depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the capacitance (that is, the junction capacitance) between the body layer and the semiconductor substrate material may be reduced even when the insulation film is not formed thickly.

It is preferable that the semiconductor substrate include: a first insulation layer disposed in a predetermined region on a semiconductor substrate material; a capacitance-adjusting semiconductor layer which is disposed on the first insulation layer and which is sufficiently thick and has a lower impurity density than that of the semiconductor substrate material; a second insulation film disposed on the capacitance-adjusting semiconductor layer; and a body layer made of a semiconductor disposed on the second insulation film.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

Further, because this semiconductor substrate includes the capacitance-adjusting semiconductor layer vertically sandwiched between the first and second insulation films, the capacitance-adjusting semiconductor layer may be made thinner in comparison with the semiconductor substrate of the first aspect of the invention when lowering the value of the junction capacitance to match with that of the semiconductor substrate of the first aspect of the invention.

It is preferable that the capacitance-adjusting semiconductor layer of the first aspect be a non-doped semiconductor layer. In this case, non-doped means having an impurity density of from approximately 10¹⁰ to 10¹⁴ cm⁻³.

With this structure, the stretch of the depletion layer from the body layer towards the semiconductor substrate material becomes sufficiently large.

According to a second aspect of the invention, a semiconductor device includes: the semiconductor substrate of the first aspect of the invention; and a transistor disposed on the body layer of the semiconductor substrate.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

Consequently, because the junction capacitance between the source diffusion layer or the drain diffusion layer (the source/drain) of the transistor and the Si substrate may be greatly reduced, the operation speed of the transistor may be increased.

A semiconductor substrate manufacturing method includes: forming, in a predetermined region on a semiconductor substrate material, a capacitance-adjusting semiconductor layer which is sufficiently thick and has a lower impurity density than that of the semiconductor substrate material; forming a sacrificial semiconductor layer on the capacitance-adjusting semiconductor layer; forming a body layer made of a semiconductor on the sacrificial semiconductor layer; forming, on the semiconductor substrate material, a support that supports the body layer on the semiconductor substrate material in a manner that the support covers the body layer; forming, in the support, an opening surface that exposes part of an end portion of the sacrificial semiconductor layer; forming a cavity between the body layer and the capacitance-adjusting semiconductor layer by etching the sacrificial semiconductor layer via the opening surface under a process condition that the sacrificial semiconductor layer has a larger etching selection ratio than that of the capacitance-adjusting semiconductor layer or the body layer; and forming an insulation film in the cavity.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

Another semiconductor substrate manufacturing method includes:

forming a first sacrificial semiconductor layer in a predetermined region on a semiconductor substrate material; forming, on the fist sacrificial semiconductor layer, a capacitance-adjusting semiconductor layer which is sufficiently thick and has a lower impurity density than that of the semiconductor substrate material; forming a second sacrificial semiconductor layer on the capacitance-adjusting semiconductor layer; forming a body layer made of a semiconductor on the second sacrificial semiconductor layer; forming, on the semiconductor substrate material, a support that supports the body layer on the semiconductor substrate material in a manner that the support covers the body layer; forming, in the support, an opening surface that exposes part of an end portion of the first sacrificial semiconductor layer and part of an end portion of the second sacrificial semiconductor layer; forming each cavity between the capacitance-adjusting semiconductor layer and the semiconductor substrate material and between the body layer and the capacitance-adjusting semiconductor layer by etching the first and second sacrificial semiconductor layers via the opening surface under a process condition that the first and second sacrificial semiconductor layers have a larger etching selection ratio than that of the capacitance-adjusting semiconductor layer or the body layer; and forming an insulation film in each cavity.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

Further, because this semiconductor substrate manufacturing method includes forming the capacitance-adjusting semiconductor layer vertically sandwiched between the first and second insulation films, the capacitance-adjusting semiconductor layer may be made thinner in comparison with the previous method when lowering the junction capacitance value to match with that of the semiconductor substrate made by the previous method.

According to a third aspect of the invention, a semiconductor substrate manufacturing method includes: forming, on a semiconductor substrate material, a capacitance-adjusting semiconductor layer which is sufficiently thick and has a lower impurity density than that of the semiconductor substrate material; forming a sacrificial semiconductor layer on the capacitance-adjusting semiconductor layer; forming a body layer made of a semiconductor on the sacrificial semiconductor layer; forming a hole that exposes the semiconductor substrate material to the body layer, the sacrificial semiconductor layer, and the capacitance-adjusting semiconductor layer; forming, on the semiconductor substrate material, a support that supports the body layer on the semiconductor substrate material in a manner that the support buries the hole and covers the body layer; forming, in the support, an opening surface that exposes part of an end portion of the sacrificial semiconductor layer; forming a cavity between the body layer and the capacitance-adjusting semiconductor layer by etching the sacrificial semiconductor layer via the opening surface under a process condition that the sacrificial semiconductor layer has a larger etching selection ratio than that of the capacitance-adjusting semiconductor layer or the body layer; and forming an insulation film in the cavity.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

According to a fourth aspect of the invention, a method for manufacturing a semiconductor substrate includes: forming a first sacrificial semiconductor layer on a semiconductor substrate material; forming, on the fist sacrificial semiconductor layer, a capacitance-adjusting semiconductor layer which is sufficiently thick and has a lower impurity density than that of the semiconductor substrate material; forming a second sacrificial semiconductor layer on the capacitance-adjusting semiconductor layer; forming a body layer made of a semiconductor on the second sacrificial semiconductor layer; forming a hole that exposes the semiconductor substrate material to the body layer, the second sacrificial semiconductor layer, the capacitance-adjusting semiconductor layer, and the first sacrificial semiconductor layer; forming, on the semiconductor substrate material, a support that supports the body layer on the semiconductor substrate material in a manner that the support buries the hole and covers the body layer; forming, in the support, an opening surface that exposes part of an end portion of the first sacrificial semiconductor layer and part of an end portion of the second sacrificial semiconductor layer; forming each cavity between the capacitance-adjusting semiconductor layer and the semiconductor substrate material and between the body layer and the capacitance-adjusting semiconductor layer by etching the first and second sacrificial semiconductor layers via the opening surface under a process condition that the first and second sacrificial semiconductor layers have a larger etching selection ratio than that of the capacitance-adjusting semiconductor layer or the body layer; and forming an insulation film in each cavity.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

Further, because the semiconductor substrate manufacturing method of the fourth aspect of the invention includes forming, the capacitance-adjusting semiconductor layer vertically sandwiched between the first and second insulation films, the capacitance-adjusting semiconductor layer may be made thinner in comparison with the third aspect of the invention when lowering the value of the junction capacitance to match with that of the semiconductor substrate made by the third aspect of the invention.

It is preferable that the semiconductor substrate manufacturing method of the third aspect of the invention further include: removing the support from the body layer by planarizing an entire upper surface of the semiconductor substrate material after the insulation film is formed in the cavity.

With this structure, because the body layer is exposed from under the support, it is possible to form the elements such as the transistor on the body layer.

According to a fifth aspect of the invention, a method for manufacturing a semiconductor device includes: after removing the support from the body layer by the previous semiconductor substrate manufacturing method, forming a transistor on the body layer.

With this structure, the depletion layer spreads more easily in the capacitance-adjusting semiconductor layer than in the semiconductor substrate material, and, thus, the depletion layer may be stretched largely from the body layer towards the semiconductor substrate material. Since the depletion layer may stretch largely, the junction capacitance may be reduced even when the insulation film is not formed thickly.

Consequently, because the junction capacitance between the source/drain and the Si substrate may be greatly reduced, the operation speed of the transistor may be increased.

According to a sixth aspect of the invention, a method for designing a semiconductor device that has an insulation film disposed in a predetermined region on a semiconductor substrate material and a body layer made of a semiconductor disposed on the insulation film includes: sandwiching a capacitance-adjusting semiconductor layer having a lower impurity density than that of the semiconductor substrate material between the insulation film and the semiconductor substrate material so as to examine a relationship of a thickness of the capacitance-adjusting semiconductor layer to a capacitance between the body layer and the semiconductor substrate material; and designing the capacitance-adjusting semiconductor layer in a predetermined thickness based on the examination result so as to match the capacitance with a predetermined value.

With this structure, the more thickly the capacitance-adjusting semiconductor layer is made, the larger the stretchable range of the depletion layer becomes. Therefore, it is possible to reduce the junction capacitance down to the predetermined value without designing the insulation thickly.

The aspects of the invention are especially suitable when applied to the so-called SBSI technique that forms the SOI structure only in a desired region on the semiconductor substrate of a bulk.

### BRIEF DESCRIPTION OF THE DRAWINGS

The invention will be described with reference to the accompanying drawings, wherein like numbers reference like elements.

FIG. 1 is a diagram showing an exemplary structure of a semiconductor device according to a first embodiment.

FIGS. 2A through 2C are diagrams showing a method for manufacturing the semiconductor device according to the first embodiment (1).

FIGS. 3A through 3C are diagrams showing the method for manufacturing the semiconductor device according to the first embodiment (2).

FIGS. 4A through 4C are diagrams showing the method for manufacturing the semiconductor device according to the first embodiment (3).

FIGS. 5A through 5C are diagrams showing simulation results of the manufacturing method according to the first embodiment.

FIG. 6 is a diagram showing an exemplary structure of a semiconductor device according to a second embodiment.

FIGS. 7A through 7C are diagrams showing a method for manufacturing the semiconductor device according to the second embodiment (1).

FIGS. 8A through 8C are diagrams showing the method for manufacturing the semiconductor device according to the second embodiment (2).

FIGS. 9A through 9C are diagrams showing the method for manufacturing the semiconductor device according to the second embodiment (3).

FIGS. 10A through 10C are diagrams showing simulation results of the manufacturing method according to the second embodiment.

FIG. 11 is a conceptual diagram showing junction capacitance.

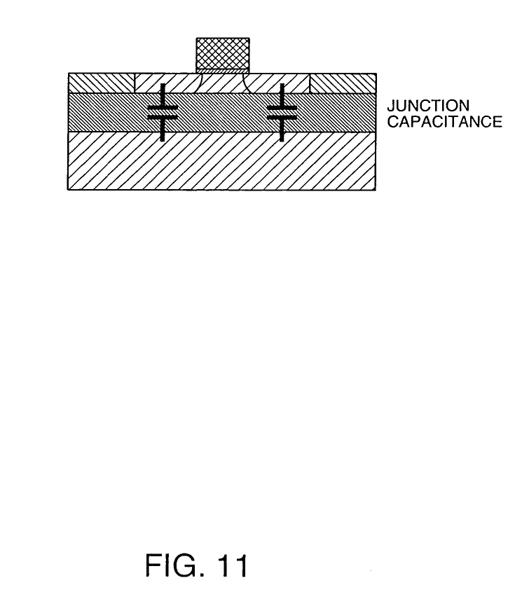

### DESCRIPTION OF EXEMPLARY EMBODIMENTS

Embodiments of the invention will now be described with reference to the drawings.

### First Embodiment

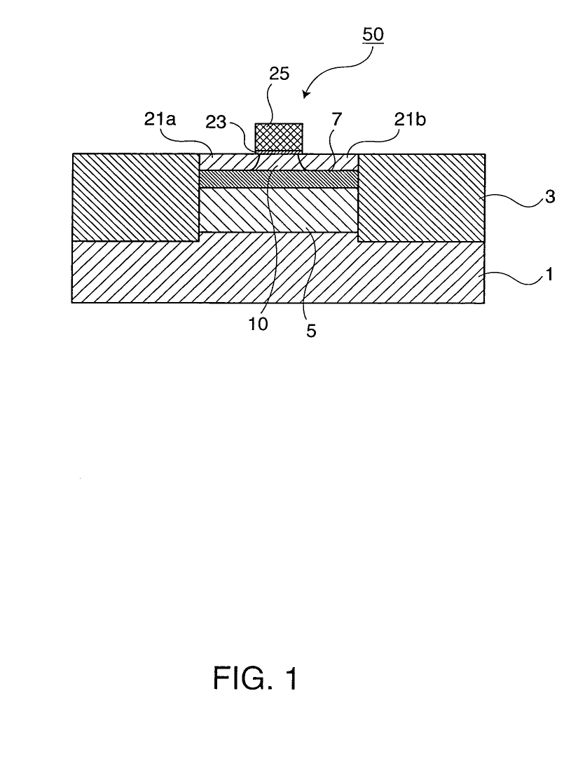

FIG. 1 is a cross-sectional diagram showing an exemplary structure of a semiconductor device according to the first embodiment. As shown in FIG. 1, this semiconductor device includes: a silicon (Si) substrate 1, an element isolation layer 3 disposed in an element isolation region of this Si substrate 1, a capacitance-adjusting Si layer 5 disposed in an element region of the Si substrate 1, a buried oxide film 7 disposed on this Si layer, a body layer 10 disposed on the buried oxide film 7, and a transistor 7 disposed on this body layer 10.

Among them, the Si substrate 1 is a bulk substrate, and its impurity density is about 10¹⁵-10¹⁹ cm⁻³, for example. Further, the element isolation layer 3 and the buried oxide film 7 are composed of SiO₂ film, for example. The thickness of the buried oxide film 7 is 60 nm, for example. Furthermore, the capacitance-adjusting Si layer 5 is composed of epitaxially grown, non-doped Si. The thickness of this Si layer is 244 nm, for example, and its impurity density is about 10¹⁰-10¹⁴ cm⁻³, for example. Further, the body layer 10 is composed of epitaxially grown Si, for example.

In contrast, the transistor 50 is a so-called SOI transistor 50 including: a source diffusion layer or a drain diffusion layer (a source/drain) 21a/21b formed on the body layer 10, a gate insulation film 23 formed on the body layer 10 between the source/drain 21a/21b, and a gate electrode 25 formed on the gate insulation film 23. The source/drain 21a/21b is, for example, an impurity diffusion layer formed by doping the body layer 10 with an n-type impurity such as phosphorus (P) or arsenic (As) or a p-type impurity such as boron (B) and by being subjected to thermal diffusion. Further, the gate insulation film 23 is composed of SiO₂ film or silicon oxide nitride (SiON) film, for example. The gate electrode 25 is composed of polysilicon film doped with an impurity, for example.

With this semiconductor device, since the depletion layer spreads more easily in the capacitance-adjusting Si layer 5 than in the Si substrate 1, it is possible to stretch the depletion layer from the source/drain 21a/21b towards the Si substrate 1 much more largely than when there is no Si layer 5 and the Si substrate 1 is set directly under the buried oxide film 7.

The method for manufacturing the semiconductor device shown in FIG. 1 will now be described.

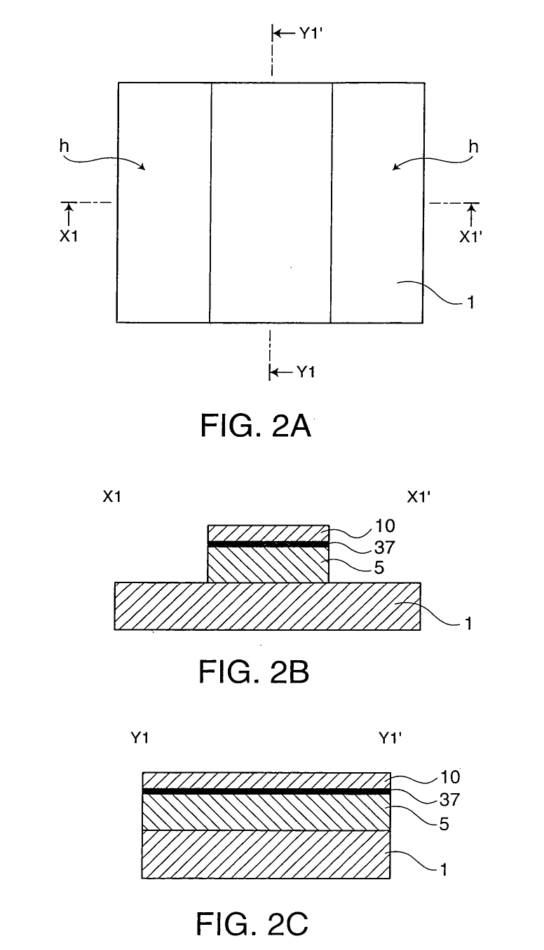

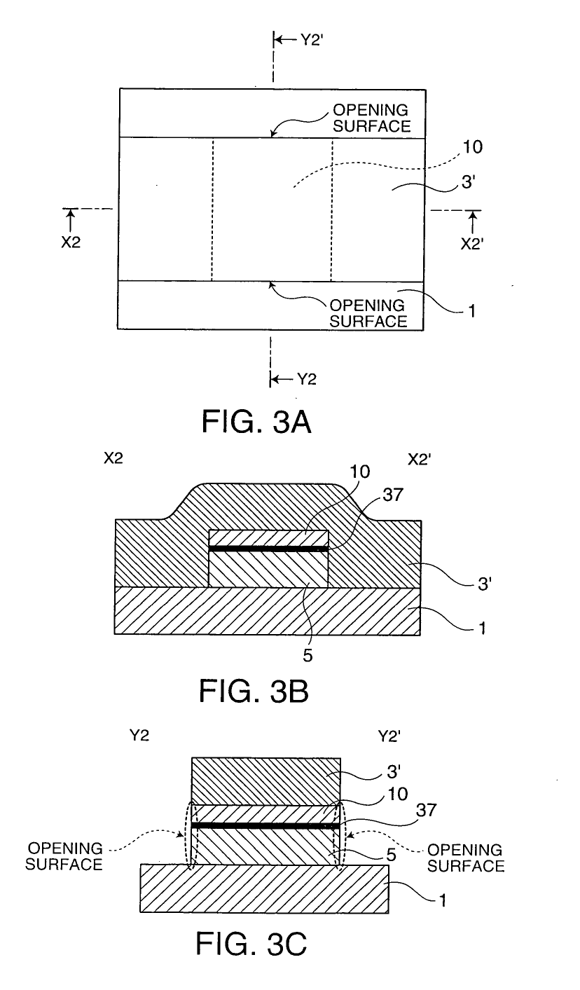

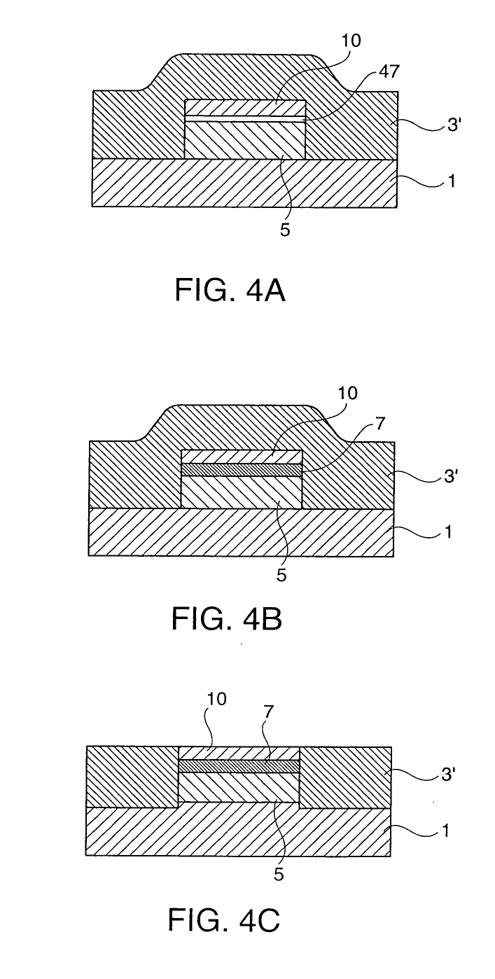

FIGS. 2A and 3A are plan diagrams showing the method for manufacturing the semiconductor device of the first embodiment of the invention. FIG. 2B is an X1-X1′ cross sectional view of FIG. 2A, and FIG. 2C is a Y1-Y1′ cross-sectional view of FIG. 2A. Also, FIG. 3B is an X2-X2′ cross-sectional view of FIG. 3A, and FIG. 3C is a Y2-Y2′ cross sectional view of FIG. 3A. Further, FIGS. 4A through 4C are cross-sectional views, on the X2-X2′ cross section, showing the semiconductor device manufacturing method of from FIG. 3B onward.

As shown in FIGS. 2A through 2C, the capacitance-adjusting Si layer 5 is first grown epitaxially on the Si substrate 1 which is a silicon wafer of a bulk. In the first embodiment, the Si layer 5 is grown in a thickness of 442 nm, for example. The impurity density of this Si layer 5 is preferably lower than the Si substrate 1, and the Si layer 5 is more preferably non-doped at about 10¹⁰-10¹⁴ cm⁻³.

Then, a SiGe layer 37 is formed on this Si, and the body layer 10 made of Si is formed thereon. These SiGe layer 37 and body layer 10 are both epitaxially grown. In this case, the SiGe layer 37 is grown in a thickness of about 30 nm, for example, and the body layer 10 is grown in a thickness of about 10-100 nm, for example.

Thereafter, a hole h for a support is formed. That is, as shown in FIGS. 2A through 2C, the body layer 10, the SiGe layer 37, and the capacitance-adjusting Si layer 5 are successively patterned using photolithography and etching techniques so as to expose part of the surface of the Si substrate 1. This exposed part is the hole h for the support. The hole h is formed at a portion outside a region (namely, the element isolation region) where elements such as the transistor 50 are formed. Further, when exposing the part of the Si substrate 1, etching may be stopped at the surface of the Si substrate 1, or the Si substrate 1 may be over-etched so as to form a recessed portion in the Si substrate 1.

Then, as shown in FIGS. 3A through 3C, a support 3′ made of SiO₂ film, for example, is formed on the entire upper part of the Si substrate 1 by a method such as chemical vapor deposition (CVD). This support is formed not only on the upper surfaces of the hole and the body layer 10 but also on the side surfaces thereof as well as the side surfaces of the SiGe layer 37 and the Si layer 5. This support 3′ supports the body layer 10 on the Si substrate 1. Further, the material constituting the support 3′ is not limited to SiO₂ but may be silicon nitride (Si₃N₄) film, for example. When constituting the support 3′ with the Si₃N₄ film, a thin SiO₂ film is to be formed as the base. The SiO₂ film that becomes the base is formed by thermal oxidation, for example.

Thereafter, as shown in FIGS. 3A through 3C, the support 3′, the body layer 10, the SiGe layer 37, and the capacitance-adjusting Si layer 5 are successively patterned using the photolithography and etching techniques, thereby forming an opening surface in the support 3′ exposing part of the side surfaces (end portions) of the body layer 10, the SiGe layer 37, and the Si layer 5.

By this patterning, the body layer 10, the SiGe layer 37, and the Si layer 5 remain only in the region on the Si substrate 1 where the elements such as the transistor 50 are formed (that is, the element formation region), and are removed completely from the element isolation region on the Si substrate 1. Further, as shown in FIGS. 3A through 3C, the opening surface exposing part of the side surface of the SiGe layer 37 is formed along the periphery of the element formation region. A part of the support 3′ where the opening surface is not formed is joined with the side surface of each of the body layer 10, the SiGe layer 37, and the Si layer 5 even after the opening surface is formed. The support 3′ keeps supporting the body layer 10 at this joined part.

Then, by bringing an etching solution such as fluoronitric acid into contact with the body layer 10, the SiGe layer 37, and the capacitance-adjusting Si layer 5 via the opening surface formed in the support 3′, the SiGe layer 37 is etched and removed. As a consequence, as shown in FIG. 4A, a cavity 47 is formed between the Si layer and the body layer 10. In the wet etching using the fluoronitric acid, because the etching selection ratio of SiGe to Si is about 100:1, for example, only the SiGe layer 37 (see FIG. 3B) sandwiched therebetween can be selectively etched without etching much of the body layer 10 and the Si layer 5.

Further, as shown in FIG. 4A, even after the SiGe layer 37 is removed to form the cavity 47, the side surface of the body layer 10 stays covered by the part of the support 3′ where the opening surface is not formed. Thus, even after the cavity 47 is formed, the body layer 10 is supported on the Si substrate 1 and stays supported.

Thereafter, the Si substrate 1 is subjected to thermal oxidation. By doing so, oxidizing species such as O₂ reach not only to the surface of the Si substrate 1 exposed from the support 3′ or to the side surfaces of the body layer 10 and the Si layer 5 but also inside the cavity 47 through the opening surface. Thus, as shown in FIG. 4B, the SiO₂ film (that is, the buried oxide film) 7 is also formed inside this cavity. Additionally, if the buried oxide film 7 is not sufficiently buried in the cavity, the SiO₂ film or the like may be deposited inside the cavity by CVD or the like after the thermal oxidation. Further, after the buried oxide film 7 is formed in the cavity, high-temperature annealing at 1,000° C. or higher may be carried out. This enables reflow of the buried oxide film 7.

Then, the upper part of the Si substrate 1 is planarized by chemical-mechanical polishing (CMP) to remove the support 3′ from the upper part of the body layer 10. As a consequence, as shown in FIG. 4C, the upper surface of the body layer 10 is exposed, and the structure in which the body layer 10 is isolated (that is, the SOI structure) can be completed on the Si substrate 1 of a bulk.

Thereafter, by thermally oxidizing the surface of the body layer 10, for example, the gate insulation film 23 (see FIG. 1) is formed on the surface of the body layer 10. Then, on the body layer 10 having the gate insulation film 23 formed thereon, a polysilicon film containing an impurity such as phosphorus is formed. Then, this polysilicon film is patterned using the photolithography and etching techniques so as to form the gate electrode 25 (see FIG. 1). Further, by using this gate electrode 25 and the like as a mask and subjecting the inner body layer 10 to ion implantation with an impurity such as As, P, or B, the source/drain 21a/21b (see FIG. 1) is formed, and the transistor 50 is thereby completed.

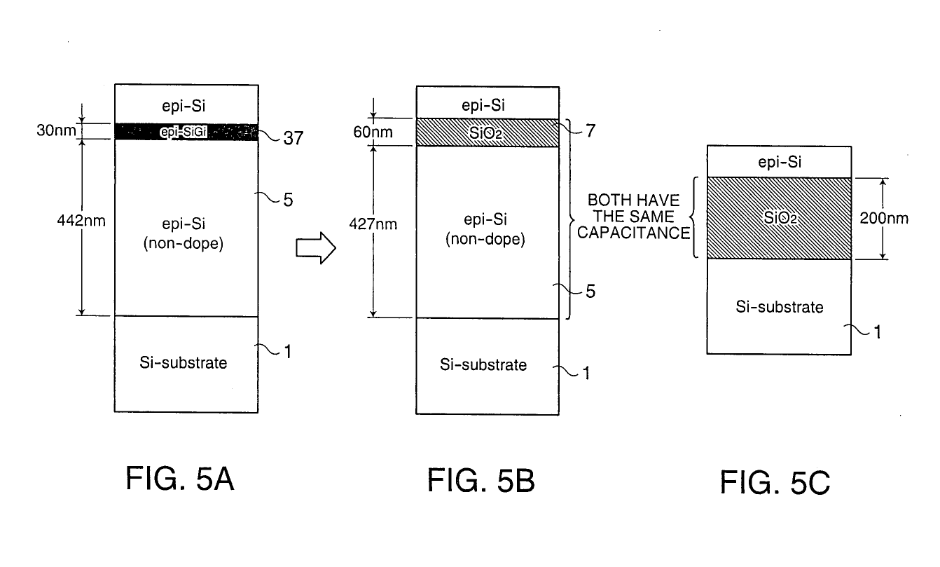

FIGS. 5A and 5B are pattern diagrams showing the simulation results of the manufacturing method of the first embodiment. For example, as shown in FIG. 5A, 442 nm of the non-doped Si layer 5 is formed on the Si substrate 1, and 30 nm of the SiGe layer 37 is formed thereon. In the simulation, if the Si layer 5 and the SiGe layer 37 are formed in such thicknesses, the thickness of the Si layer 5 upon formation of the buried oxide film 7 becomes 427 nm as shown in FIG. 5B. Further, the buried oxide film 7 is formed in a thickness of 60 nm. As shown in FIGS. 5B and 5C, the simulation results indicate that the junction capacitance of a stack of the Si layer 5 in 427 nm and the buried oxide film 7 in 60 nm is equal to the junction capacitance of the buried oxide film in 200 nm.

As thus indicated, according to the semiconductor device and its manufacturing method of the first embodiment of the invention, because the depletion layer spreads more easily in the capacitance-adjusting Si layer 5 than in the Si substrate 1, the depletion layer can be stretched much more largely from the source/drain 21a/21b towards the Si substrate 1 than when there is no Si layer 5 (that is, when the buried oxide film 7 is formed directly on the Si substrate 1). Therefore, it is possible to reduce the capacitance (namely, the junction capacitance) between the body layer 10 and the Si substrate 1 without thickly forming the buried oxide film.

Further, Si has higher thermal conductivity than does SiO₂. According to some embodiments of the invention, because the buried oxide film can be made thinner than an ordinary SOI structure while reducing the junction capacitance at the same time, it is possible to efficiently release the heat generated at the transistor 50 to the Si substrate 1. Thus, it is possible to reduce the heat staying inside the device.

Moreover, the method for designing the semiconductor substrate according to one embodiment of the invention, which is a method for designing a semiconductor substrate having the buried oxide film 7 disposed on the Si substrate 1 in the element formation region and the body layer 10 disposed on this buried oxide film 7, includes: sandwiching the capacitance-adjusting Si layer 5 between the buried oxide film 7 and the Si substrate 1 so as to examine relationship of the thickness of this Si layer 5 to the junction capacitance between the body layer 10 and the Si substrate 1, and designing the capacitance-adjusting Si layer 5 in a predetermined thickness based on the examination result so as to match the junction capacitance with a predetermined value. The impurity density of the capacitance-adjusting Si layer 5 is set lower than the Si substrate 1.

With this structure, it is the thicker the capacitance-adjusting Si layer 5 is, the more widely the stretchable range of the depletion layer becomes. Therefore, without designing the buried oxide film 7 to be thick, it is possible to reduce the junction capacitance down to the predetermined value.

In the first embodiment, the element formation region corresponds to the “predetermined region” in the specification, and the Si substrate 1 corresponds to the “semiconductor substrate material” in the specification. Further, the Si layer 5 corresponds to the “capacitance-adjusting semiconductor layer” in the specification, and the buried oxide film 7 corresponds to the “insulation film” in the specification. Also, the SiGe layer 37 corresponds to the “sacrificial semiconductor layer” in the specification.

In the first embodiment, it has been explained in that the capacitance-adjusting Si layer 5, the SiGe layer 37, and the body layer 10 are successively grown epitaxially on the entire surface of Si substrate 1, and, thereafter, these films are removed from the element isolation region to remain only in the element formation region. However, these layers may not be formed on the entire surface of the Si substrate 1 but formed only in the element formation region and not in the element isolation region. For example, the Si layer 5, SiGe layer 7, and the body layer 10 are selectively grown epitaxially in a state that only the surface of the Si substrate 1 in the element isolation region is covered by the SiO₂ film. By this method, also, because the support 3′ can be formed over the body layer 10 on the Si substrate 1 and because the opening surface exposing the side surface of the SiGe layer 37 can be formed in this support 3′, it is possible to form the cavity 47 in the element formation region.

### Second Embodiment

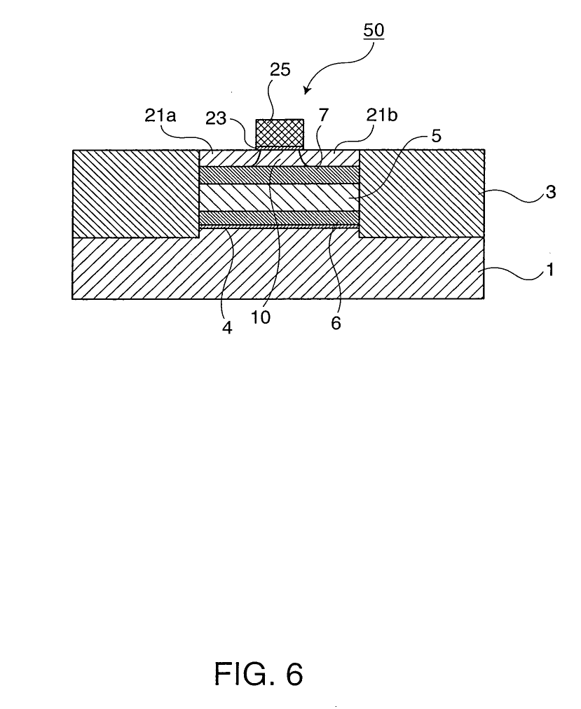

FIG. 6 is a cross-sectional diagram showing an exemplary structure of the semiconductor device according to the second embodiment. In FIG. 6, the same elements are allotted with the same reference numbers as in FIG. 1, and their descriptions will not be repeated.

As shown in FIG. 6, this semiconductor device is composed of: the Si substrate 1, the element isolation layer 3, a first buried oxide film 6 disposed on the element region of the Si substrate 1, the capacitance-adjusting Si layer 5 disposed on this buried oxide film 6, a second buried oxide film 7 disposed on this Si layer 5, the body layer 10 disposed on the second buried oxide film 7, and the transistor 50 disposed on this body layer 10. The first and second buried oxide films 6 and 7 are composed of SiO₂ film, for example.

As shown in FIG. 6, with this semiconductor device, the capacitance-adjusting Si layer 5 is vertically sandwiched between the first and second buried oxide films 6 and 7. In the second embodiment, the thickness of the Si layer 5 is 244 nm, for example. Also, the thickness of each of the first and second buries oxide films 6 and 7 is 60 nm, for example.

The method for manufacturing the semiconductor device shown in FIG. 6 will now be described.

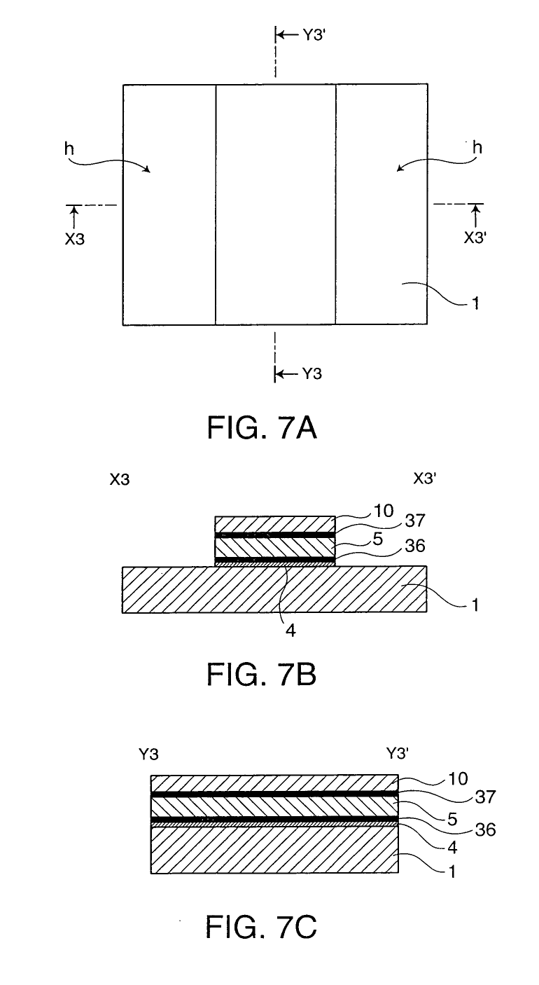

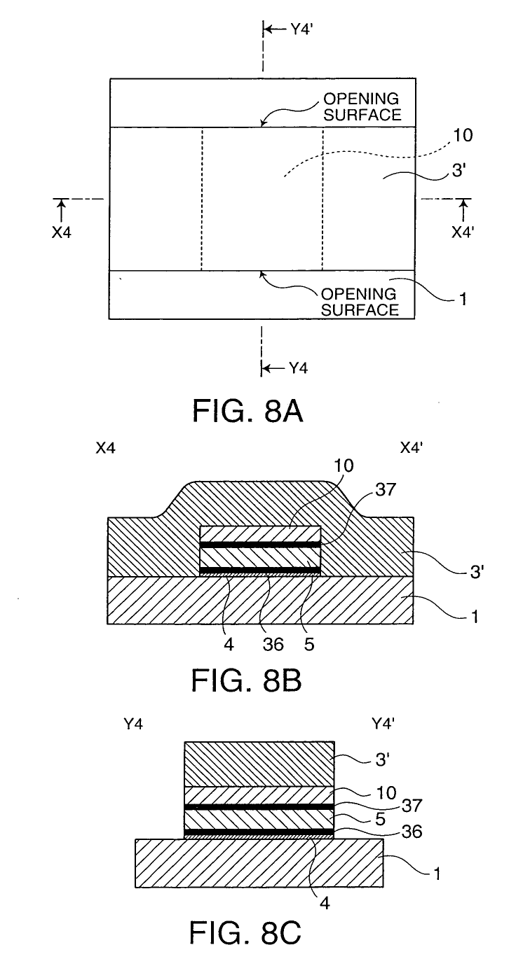

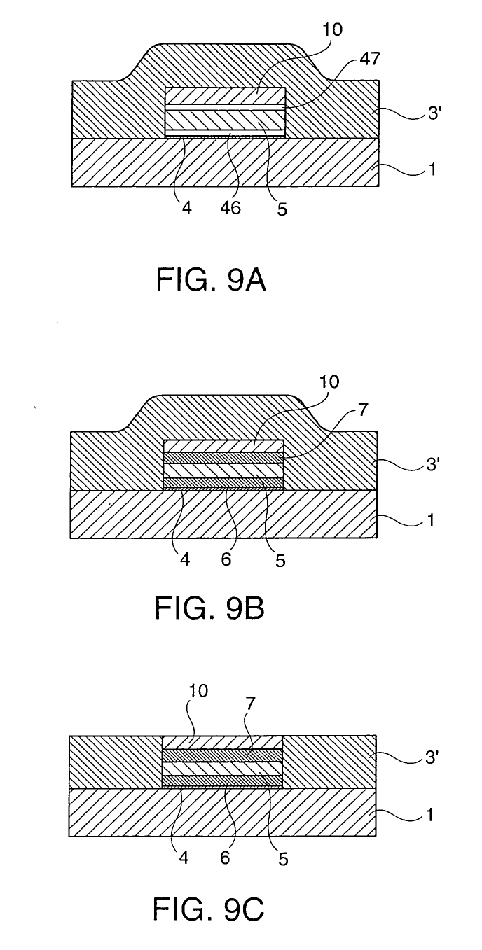

FIGS. 7A and 8A are plan diagrams showing the method for manufacturing the semiconductor device according to the second embodiment of the invention. FIG. 7B is an X3-X3′ cross-sectional diagram of FIG. 7A, and FIG. 7C is a Y3-Y3′ cross-sectional diagram of FIG. 2A. FIG. 8B is an X4-X4′ cross-sectional diagram of FIG. 8A, and FIG. 8C is a Y4-Y4′ cross-sectional diagram of FIG. 8A. Further, FIGS. 9A through 9C are cross-sectional diagrams, on the X4-X4′ cross section, showing the method for manufacturing the semiconductor device of from FIG. 8B onward.

As shown in FIGS. 7A through 7C, a Si layer 4 is first epitaxially grown on the Si substrate 1 that is the silicon wafer of a bulk. This Si layer 4 is a buffer layer to prevent defects from occurring in the crystal structure of a SiGe layer 36 to be formed on the Si layer 4, and has a thickness of about 20 nm, for example.

Then, the first SiGe layer 36 is grown in a thickness of 30 nm on this Si layer 4. This SiGe layer 36 is grown epitaxially, for example. Then, the capacitance-adjusting Si layer 5 is grown epitaxially on this SiGe layer 36. In the second embodiment, the Si layer 5 is grown in a thickness of about 274 nm, for example. As in the first embodiment, in the second embodiment, also, the impurity density of this Si layer 5 is preferably lower than the Si substrate 1, and the Si layer 5 is more preferably non-doped at about 10¹⁰-10¹⁴ cm⁻³.

Thereafter, the second SiGe layer 37 is formed on this Si layer 5, and the body layer 10 made of Si is formed thereon. These SiGe layer 37 and body layer 10 are both grown epitaxially. In this case, the SiGe layer 37 is formed in a thickness of about 30 nm, for example, and the body layer 10 is formed in a thickness of about 10-100 nm, for example.

Then, the hole h for the support 3′ is formed. That is, as shown in FIGS. 7A through 7C, the body layer 10, the second SiGe layer 37, the capacitance-adjusting Si layer 5, the first SiGe layer 36, and the Si layer 4 for buffer are successively patterned using the photolithography and etching techniques so as to expose part of the surface of the Si substrate 1. This exposed part is the hole h for the support 3′. This hole h is formed at a portion outside a region (namely, the element isolation region) where the elements such as the transistor 50 are formed.

Then, as shown in FIGS. 8A through 8C, the support 3′ made of SiO₂ film is formed on the entire upper part of the Si substrate 1. The support 3′ supports the body layer 10 and the Si layer 5 on the Si substrate 1.

Thereafter, as shown in FIGS. 8A through 8C, the support 3′, the body layer 10, the second SiGe layer 37, the capacitance-adjusting Si layer 5, the first SiGe layer 36, and the Si layer 4 for buffer are successively patterned using the photolithography and etching techniques, thereby forming an opening surface in the support 3′ exposing part of the side surfaces (end portions) of the body layer 10, the SiGe layer 37, the Si layer 5, the SiGe layer 37, and the Si layer 4.

By this patterning, the body layer 10, the SiGe layer 37, the Si layer 5, the SiGe layer 36, and the Si layer 4 remain only in the element formation region on the Si substrate 1, and are removed completely from the element isolation region on the Si substrate 1. Further, as shown in FIGS. 8A through 8C, the opening surface exposing part of the side surfaces of the SiGe layers 36 and 37 is formed along the periphery of the element formation region.

Then, by bringing the etching solution such as fluoronitric acid into contact with the body layer 10, the SiGe layer 37, the Si layer 5, the SiGe layer 36, and the Si layer 4 via the opening surface formed in the support 3′, the SiGe layers 36 and 37 are etched and removed. As a result, as shown in FIG. 9A, cavities 46 and 47 are respectively formed between the Si layer 4 for buffer and the capacitance-adjusting Si layer 5 and between the Si layer 5 and the body layer 10.

Thereafter, the Si substrate 1 is subjected to thermal oxidation, and, as shown in FIG. 9B, each of the SiO₂ films (that is, the buried oxide films) 6 and 7 is formed inside each cavity. Additionally, similarly to the first embodiment, if the buried oxide films 6 and 7 are not sufficiently buried in the cavities 46 and 47, the SiO₂ film or the like may be deposited inside the cavities by CVD or the like after the thermal oxidation. Also, after the buried oxide films 6 and 7 are formed in the cavities, high-temperature annealing at 1,000° C. or higher may be carried out. This enables the reflow of the buried oxide films 6 and 7.

Then, the upper part of the Si substrate 1 is planarized by CMP, and the support 3′ is removed from the upper part of the body layer 10. As a consequence, as shown in FIG. 9C, the upper surface of the body layer 10 is exposed, and the structure in which the body layer 10 is isolated (that is, the SOI structure) can be formed on the Si substrate 1 of a bulk.

Thereafter, by thermally oxidizing the surface of the body layer 10, for example, the gate insulation film 23 (see FIG. 6) is formed on the surface of the body layer 10, and the gate electrode 25 (see FIG. 6) is formed. Further, using this gate electrode 25 and the like as a mask and subjecting the inner body layer 10 to ion implantation with an impurity such as As, P, or B, the source/drain 21a/21b (see FIG. 6) is formed, and the transistor 50 is thereby completed.

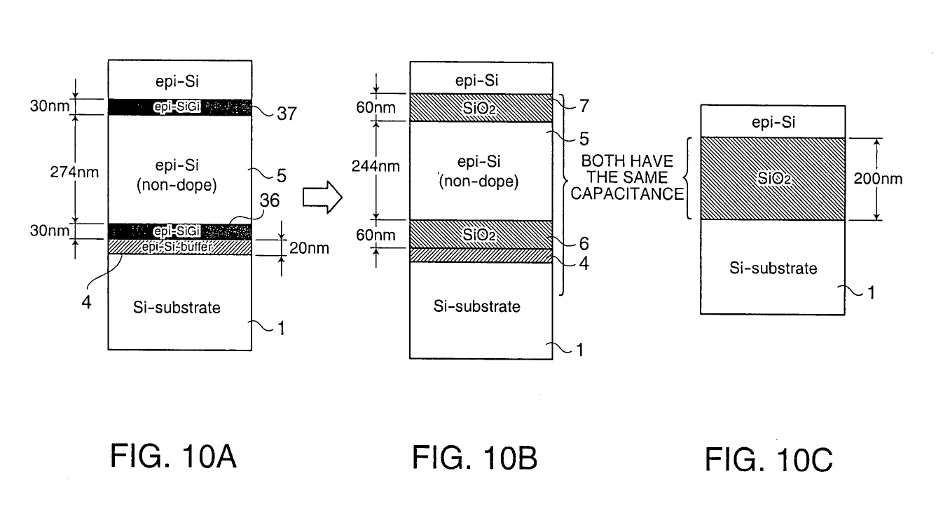

FIGS. 10A through 10C are pattern diagrams showing the simulation results of the manufacturing method of the second embodiment. For example, as shown in FIG. 10A, 20 nm of the Si layer 4 for buffer is formed on the Si substrate 1, and 30 nm of the first SiGe layer 36 is formed thereon. Then, 274 nm of the non-doped Si layer 5 is formed, and 30 nm of the second SiGe layer 37 is formed thereon. In the simulation, when the Si layers 4 and 5 and the SiGe layers 36 and 37 are formed in such thicknesses, the thickness of the Si layer 5 upon formation of the buried oxide films 6 and 7 becomes about 244 nm as shown in FIG. 10B. Also, the buried oxide films 6 and 7 are both formed in a thickness of about 60 nm. Further, the thickness of the Si layer 4 for buffer is about 5 nm. As shown in FIGS. 10B and 10C, the simulation results indicate that the junction capacitance of a stack of the Si layer in 244 nm and the buried oxide films 6 and 7 in 60 nm is equal to the junction capacitance of the buried oxide film in 200 nm.

As thus indicated, according to the semiconductor device and its manufacturing method of the second embodiment of the invention, because the depletion layer can be stretched much more largely from the source/drain 21a/21b towards the Si substrate 1, it is possible to reduce the capacitance (namely, the junction capacitance) between the body layer 10 and the Si substrate 1 without thickly forming the buried oxide film.

Further, in the second embodiment, because the capacitance-adjusting Si layer 5 is vertically sandwiched between the buried oxide films 6 and 7, the capacitance-adjusting Si layer 5 can be made thinner than the first embodiment when lowering the junction capacitance of the second embodiment to match with the first embodiment. As a consequence, the semiconductor substrate material can be made thinner, and the time required for the epitaxial growth of the Si layer 5 can be shortened.

Furthermore, with the transistor 50 shown in FIG. 6, since the Si layer becomes a floating state electrically, fine adjustment of the threshold of the transistor 50 is possible by extracting electrons from the Si substrate 1, for example. The transistor 50 can also be applied to nonvolatile memory.

In the second embodiment, the buried oxide film 6 corresponds to the “first insulation film” in the specification, and the buried oxide film 7 corresponds to the “second insulation film” in the specification. Also, the SiGe layer 36 corresponds to the “first sacrificial semiconductor layer” in the specification, and the SiGe layer 37 corresponds to the “second sacrificial semiconductor layer” in the specification. Other corresponding relations are the same as those in the first embodiment.

In addition, in the embodiments of the invention, it has been explained that the material of the “semiconductor substrate material” is Si; the material of the “(first and second) sacrificial semiconductor layers” is SiGe; and the material of the “capacitance-adjusting semiconductor layer” and the “body layer 10” is Si. However, other materials may be used. For example, the material of the “semiconductor substrate material” may be Si, Ge, SiGe, SiC, SiSn, PbS, GaAs, InP, GaP, GaN, or ZnSe. Also, the material of the “sacrificial semiconductor layers” may be such that has a larger etching selection ratio than that of the Si substrate 1, the capacitance-adjusting semiconductor layer, or the body layer 10. For example, the materials of the “sacrificial semiconductor layers,” the “capacitance-adjusting semiconductor layer,” and the “body layer 10” may be combinations selected from Si, Ge, SiGe, SiC, SiSn, PbS, GaAs, InP, GaP, GaN, and ZnSe.

The entire disclosure of Japanese Patent application No. 2005-212748, field Jul. 22, 2005 is expressly incorporated by reference herein.

What is claimed is:

1. A semiconductor substrate, comprising:
a capacitance-adjusting semiconductor layer which is disposed in a predetermined region on a semiconductor substrate material and which is sufficiently thick and has a lower impurity density than that of the semiconductor substrate material;
a first insulation film disposed on the capacitance-adjusting semiconductor layer; and
a body layer made of a semiconductor disposed on the first insulation film.

2. The semiconductor substrate according to claim 1, further comprising a second insulation film disposed between the semiconductor substrate material and the capacitance-adjusting semiconductor layer.

3. The semiconductor substrate according to claim 1, wherein the capacitance-adjusting semiconductor layer is a non-doped semiconductor layer.

4. A semiconductor device, comprising:
the semiconductor substrate of claim 1; and
a transistor disposed on the body layer of the semiconductor substrate.

5. A method for manufacturing a semiconductor substrate, comprising:
forming, on a semiconductor substrate material, a capacitance-adjusting semiconductor layer which is sufficiently thick and has a lower impurity density than that of the semiconductor substrate material;
forming a sacrificial semiconductor layer on the capacitance-adjusting semiconductor layer;
forming a body layer made of a semiconductor on the sacrificial semiconductor layer;
forming a hole that exposes the semiconductor substrate material to the body layer, the sacrificial semiconductor layer, and the capacitance-adjusting semiconductor layer;
forming, on the semiconductor substrate material, a support that supports the body layer on the semiconductor substrate material in a manner that the support buries the hole and covers the body layer;
forming, in the support, an opening surface that exposes part of an end portion of the sacrificial semiconductor layer;
forming a cavity between the body layer and the capacitance-adjusting semiconductor layer by etching the sacrificial semiconductor layer via the opening surface under a process condition that the sacrificial semiconductor layer has a larger etching selection ratio than that of the capacitance-adjusting semiconductor layer or the body layer; and
forming an insulation film in the cavity.

6. A method for manufacturing a semiconductor substrate, comprising:
forming a first sacrificial semiconductor layer on a semiconductor substrate material;
forming, on the fist sacrificial semiconductor layer, a capacitance-adjusting semiconductor layer which is sufficiently thick and has a lower impurity density than that of the semiconductor substrate material;
forming a second sacrificial semiconductor layer on the capacitance-adjusting semiconductor layer;
forming a body layer made of a semiconductor on the second sacrificial semiconductor layer;
forming a hole that exposes the semiconductor substrate material to the body layer, the second sacrificial semiconductor layer, the capacitance-adjusting semiconductor layer, and the first sacrificial semiconductor layer;
forming, on the semiconductor substrate material, a support that supports the body layer on the semiconductor substrate material in a manner that the support buries the hole and covers the body layer;
forming, in the support, an opening surface that exposes part of an end portion of the first sacrificial semiconductor layer and part of an end portion of the second sacrificial semiconductor layer;
forming each cavity between the capacitance-adjusting semiconductor layer and the semiconductor substrate material and between the body layer and the capacitance-adjusting semiconductor layer by etching the first and second sacrificial semiconductor layers via the opening surface under a process condition that the first and second sacrificial semiconductor layers have a larger etching selection ratio than that of the capacitance-adjusting semiconductor layer or the body layer; and
forming an insulation film in each cavity.

7. The method for manufacturing the semiconductor substrate according to claim 5, further comprising removing the support from the body layer by planarizing an entire upper surface of the semiconductor substrate material after the insulation film is formed in the cavity.

8. A method for manufacturing a semiconductor device, comprising:
after removing the support from the body layer by the semiconductor substrate manufacturing method of claim 7,
forming a transistor on the body layer.

9. A method for designing a semiconductor substrate that has an insulation film disposed in a predetermined region on a semiconductor substrate material and a body layer made of a semiconductor disposed on the insulation film, comprising:
sandwiching a capacitance-adjusting semiconductor layer having a lower impurity density than that of the semiconductor substrate material between the insulation film and the semiconductor substrate material so as to examine a relationship of a thickness of the capacitance-adjusting semiconductor layer to a capacitance between the body layer and the semiconductor substrate material; and
designing the capacitance-adjusting semiconductor layer in a predetermined thickness based on the examination result so as to match the capacitance with a predetermined value.

10. The method for manufacturing the semiconductor substrate according to claim 6, further comprising removing the support from the body layer by planarizing an entire upper surface of the semiconductor substrate material after the insulation film is formed in the cavity.
